(19) United States
(12) Patent Application Publication
(10) Pub. No.: US 2008/0277802 A1
(43) Pub. Date: Nov. 13, 2008

(54) Flip-chip semiconductor package and package substrate applicable thereto

(75) Inventors: Kuo-Ching Tsai, Taichung Hsien (TW); Chang-Fu Lin, Taichung (TW)

Correspondence Address: Edwards Angell Palmer & Dodge LLP, P.O. Box 55874, Boston, MA, 02205, US

(73) Assignee: Siliconware Precision Industries Co., Ltd., Taichung (TW)

(21) Appl. No.: 12/151,904

(22) Filed: May 8, 2008

(30) Foreign Application Priority Data
May 10, 2007 (TW) 096116583

(51) Int. Cl. H01L 23/488

(52) U.S. Cl. 257/778; 257/E23.023

(57) ABSTRACT

A flip-chip semiconductor package structure and a package substrate applicable thereto are disclosed. The package substrate includes a body having at least a chip-attach area disposed thereon; a plurality of solder pads disposed in the chip-attach area and arranged at different intervals; and a fluid-disturbing portion disposed in the chip-attach area at a position where the solder pads are loosely arranged. A flip-chip semiconductor chip is mounted on the solder pads via conductive bumps and an underfill material is filled between the package substrate and the flip-chip semiconductor chip, the underfill material encapsulating the conductive bumps and the fluid-disturbing portion. By protrudingly disposing the fluid-disturbing portion at a position where the conductive bumps are loosely arranged, that is, the conductive bumps having bigger intervals therebetween, gap between the package substrate and the flip-chip semiconductor chip can be reduced so as to increase capillary attraction generated by capillary phenomenon, thereby balancing flow rate of the underfill material between the conductive bumps that are arranged at different intervals and thus avoiding problems of void formation, subsequent popcorn effect or delamination as encountered in the prior art.

### BACKGROUND OF THE INVENTION

1. Field of the Invention

The present invention relates generally to a semiconductor package structure and a chip carrier thereof, and more particularly to a flip-chip semiconductor package structure and a package substrate applicable thereto.

2. Description of Related Art

In a flip-chip semiconductor package, active surface of at least a semiconductor chip is electrically connected to surface of a substrate through a plurality of solder bumps. Such structure not only reduces package volume and makes scale of the substrate much closer to that of the semiconductor chip, but also eliminates the need of wire design and accordingly reduces resistance and improves electrical performance. Therefore, flip-chip semiconductor packages have become a mainstream package technique for next generation semiconductor chips and electronic components.

FIG. 1 is a sectional diagram of a conventional flip-chip semiconductor package. As shown in FIG. 1, a flip-chip semiconductor chip 10 is mounted on and electrically connected to a substrate 11 through a plurality of conductive bumps 13. An underfill material 12 is filled between the flip-chip semiconductor chip 10 and the substrate 11 for encapsulating the conductive bumps 13 and increasing strength of the conductive bumps 13 and meanwhile supporting the flip-chip semiconductor chip 10. The underfill material 12 is typically dispensed between the flip-chip semiconductor chip 10 and the substrate 11, and then flows into and fills gaps between the substrate 11 and the semiconductor chip 10 and in between the conductive bumps 13 by capillary attraction generated by capillary phenomenon. Related techniques are disclosed by U.S. Pat. No. 6,225,704, No. 6,074,895, No. 6,372,544 and No. 5,218,234. However, in the case the conductive bumps are arranged in an area array and interval between the conductive bumps is much small, e.g. smaller than 180 μm, smooth flowing of the underfill material can be prevented. Accordingly, voids can be formed in the underfill material and even underfill delamination can occur, thus adversely affecting the product quality.

To overcome the above drawbacks, U.S. Pat. No. 5,804,881 discloses a flip-chip semiconductor package structure, wherein a V-shaped channel is formed in a solder mask layer that covers surface of the substrate for improving flow of the underfill material.

However, such a method is applicable only when conductive bumps are arranged with a same interval. If conductive bumps are arranged at different intervals or interval between conductive bumps located at central portions is bigger than interval between conductive bumps located at peripheral portions, the above-described method cannot overcome problems of air trap and void formation caused by an uneven capillary attraction of capillary phenomenon during dispensing of an underfill material.

Referring to FIG. 2, in a FCBGA structure with conductive bumps 13 arranged at a same interval, capillary attraction of capillary phenomenon is same during filling of an underfill material 12 and flow direction of the underfill material is easy to control.

However, in a FCBGA structure with conductive bumps arranged at different intervals, as shown in FIGS. 3A and 3B, during a dispensing process, the underfill material 12 experiences different capillary attractions of capillary phenomenon due to different intervals between the conductive bumps 13 and therefore the underfill material 12 obtains different flow rates. In a region where conductive bumps 13 have big interval, the conductive bumps 13 are loosely arranged and capillary attraction is weak. Accordingly, the underfill material 12 in this region obtains a slow flow rate. Oppositely, in a region where conductive bumps 13 have small interval, the conductive bumps are closely arranged and capillary attraction is strong. Accordingly, the underfill material 12 in this region obtains a fast flow rate. Therefore, after the dispensing process is completed, voids 15 can be formed due to air trap between the semiconductor chip and the substrate, which can lead to a popcorn effect in subsequent heat cycling and even lead to a problem of delamination.

Therefore, how to overcome void formation and even problems of popcorn and delamincation caused by different flow rates of underfill material in a flip-chip semiconductor package structure with conductive bumps arranged at different intervals has become urgent.

### SUMMARY OF THE INVENTION

According to the above drawbacks, an objective of the present invention is to provide a flip-chip semiconductor package structure and a package substrate applicable thereto, wherein a uniform capillary attraction can be provided for underfill material.

Another objective of the present invention is to provide a flip-chip semiconductor package structure and a package substrate applicable thereto so as to prevent formation of voids caused by different flow rates of the underfill material due to different intervals between conductive bumps as well as subsequent popcorn and delamination problems.

In order to attain the above and other objectives, the present invention discloses a package substrate, which comprises: a body having at least a chip-attach area disposed thereon; a plurality of solder pads disposed in the chip-attach area and arranged at different intervals; and a fluid-disturbing portion disposed in the chip-attach area at a position where the solder pads are loosely arranged.

The present invention further discloses a flip-chip semiconductor package structure using the above-described package substrate. The flip-chip semiconductor package structure comprises: a package substrate, comprising: a body having at least a chip-attach area disposed thereon, a plurality of solder pads disposed in the chip-attach area and arranged at different intervals, and a fluid-disturbing portion disposed in the chip-attach area at a position where the solder pads are loosely arranged; a flip-chip semiconductor chip mounted on and electrically connected to the solder pads in the chip-attach area through a plurality of conductive bumps; and an underfill material filled between the package substrate and the flip-chip semiconductor chip and encapsulating the conductive bumps and the fluid-disturbing portion.

The fluid-disturbing portion can be an insulating body laid in the chip-attach area of the package substrate, such as an epoxy resin or a solder mask layer. The fluid-disturbing portion can have a strip shape, a point shape, a block shape, a grid shape and so on.

Therefore, according to the present invention, a fluid-disturbing portion is protrudingly disposed in a chip-attach area of a package substrate at a position where the solder pads are loosely arranged, that is, the fluid-disturbing portion is protrudingly disposed at a position where the conductive bumps for mounting of a flip-chip semiconductor chip are loosely arranged, such that gap between the flip-chip semiconductor chip and the package substrate or gap between the fluid-disturbing portion and the conductive bumps can be reduced, thereby increasing capillary attraction of capillary phenomenon and further balancing flow rate of the underfill material between the conductive bumps that are arranged at different intervals. As a result, voids formation and subsequent popcorn effect or delamination problem can be prevented.

### BRIEF DESCRIPTION OF DRAWINGS

FIG. 1 is a sectional diagram of a conventional flip-chip semiconductor package;

FIG. 2 is a diagram showing flow state of an underfill material between conductive bumps arranged with a same interval;

FIGS. 3A and 3B are diagrams showing flow states of an underfill material between conductive bumps arranged at different intervals;

FIGS. 4A and 4B are respectively planar and sectional diagrams of a package substrate according to a first embodiment of the present invention;

FIG. 5 is a sectional diagram of a flip-chip semiconductor package structure according to a first embodiment of the present invention;

FIGS. 6A and 6B are sectional diagrams of a package substrate according to a second embodiment of the present invention; and

FIG. 7 is a sectional diagram of a flip-chip semiconductor package structure according to a second embodiment of the present invention.

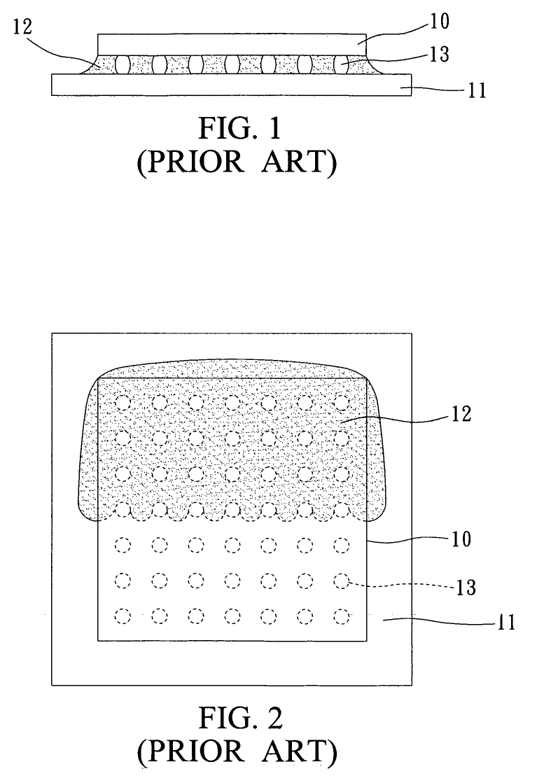

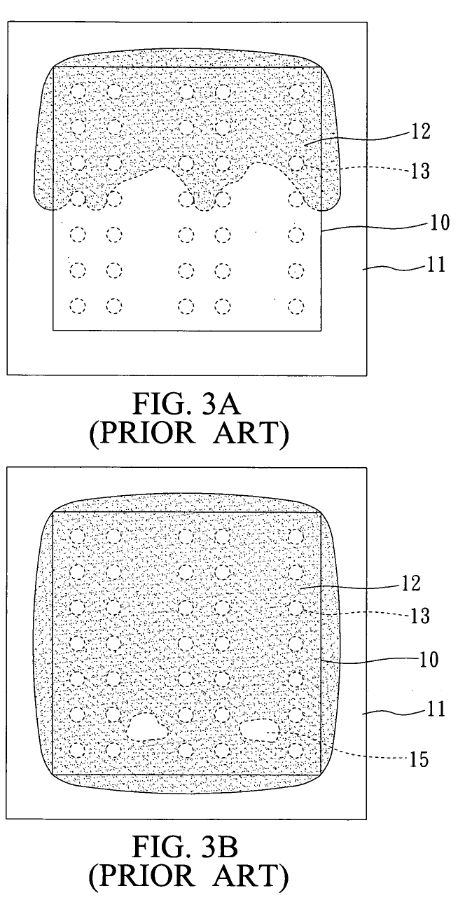

### DETAILED DESCRIPTION OF PREFERRED EMBODIMENTS

The following illustrative embodiments are provided to illustrate the disclosure of the present invention, these and other advantages and effects can be apparent to those skilled in the art after reading the disclosure of this specification. The present invention can also be performed or applied by other different embodiments. The details of the specification may be on the basis of different points and applications, and numerous modifications and variations can be made without departing from the spirit of the present invention.

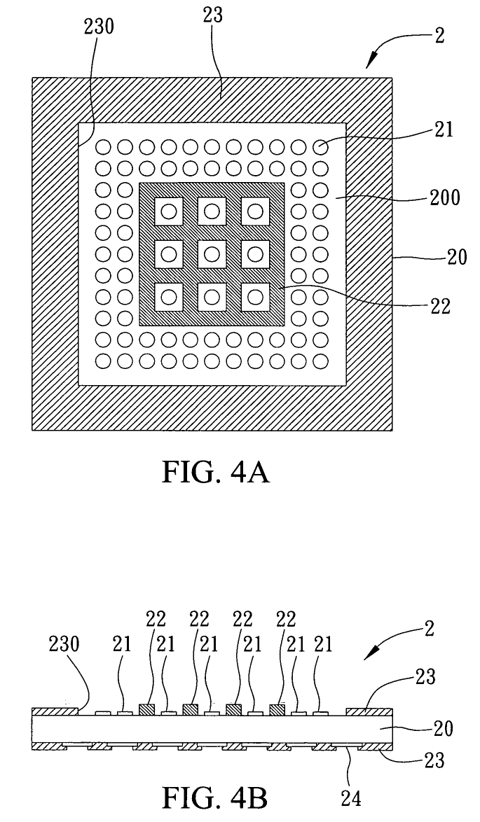

FIGS. 4A and 4B are diagrams of a package substrate applicable to a flip-chip semiconductor package structure according to the present invention, wherein FIG. 4B is sectional diagram of FIG. 4A.

The package substrate 2 comprises a body 20 having at least a chip-attach area 200 disposed thereon; a plurality of solder pads 21 disposed in the chip-attach area 200 and arranged at different intervals; and a fluid-disturbing portion 22 disposed in the chip-attach area 200 at a position where the solder pads 21 are loosely arranged.

A solder mask layer 23 is formed to cover surfaces of the body 20 and an opening 230 is formed in the solder mask layer 23 for exposing the chip-attach area 200 with the solder pads 21 disposed therein and arranged at different intervals. Also, opposite to the surface of the package substrate 2 having the solder pads 21 disposed thereon, another surface of the package substrate 2 is disposed with a plurality of solder ball pads 24, which is exposed from the solder mask layer 23.

The fluid-disturbing portion 22 is disposed in the chip-attach area 200 at a position where the solder pads 21 are loosely arranged. The fluid-disturbing portion 22 can be an epoxy resin or a solder mask layer that is protrudingly disposed on the body 20 of the substrate. The fluid-disturbing portion 22 can be formed by screen printing or laid in the chip-attach area 200 at the same time when the solder mask layer 23 is formed on the body.

Further, the fluid-disturbing portion 22 is shaped corresponding to shape and position of the solder pads 21 that are arranged at different intervals. For example, the fluid-disturbing portion 22 can have a grid shape as shown in the drawing, or have a point shape, a block shape or a strip shape.

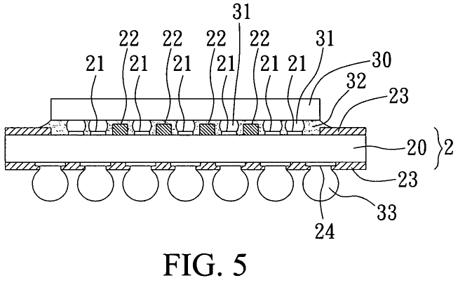

FIG. 5 is a sectional diagram of a flip-chip semiconductor package structure according to the present invention.

The flip-chip semiconductor package structure uses an above-described package substrate. The flip-chip semiconductor package structure comprises: a package substrate 2, which comprises a body 20 with at least a chip-attach area disposed thereon, a plurality of solder pads 21 disposed in the chip-attach area and arranged at different intervals, and a fluid-disturbing portion 22 disposed in the chip-attach area at a position where the solder pads 21 are loosely arranged; a flip-chip semiconductor chip 30 mounted on and electrically connected to the solder pads 21 through a plurality of conductive bumps 31; and an underfill material 32 filled between the package substrate 2 and the flip-chip semiconductor chip 30 and encapsulating the conductive bumps 31 and the fluid-disturbing portion 22. Further, solder balls 33 are mounted on the solder ball pads 24 of the package substrate 2 such that the flip-chip semiconductor chip 30 can be electrically connected with an external device through the solder balls 33.

The fluid-disturbing portion 22 is protrudingly disposed on the body 20 of the package substrate. Thickness and width of the fluid-disturbing portion 22 are designed such that capillary rate induced by distance from the fluid-disturbing portion 22 to the flip-chip semiconductor chip 30 and capillary rate induced by distance from the fluid-disturbing portion 22 to the conductive bumps 31 can be close to or same as capillary rate at a position where the conductive bumps are closely arranged, thereby preventing void formation resulted from uneven flow rate of the underfill material 32.

Therefore, according to the present invention, a fluid-disturbing portion is protrudingly disposed in a chip-attach area of a package substrate at a position where the solder pads are loosely arranged, that is, the fluid-disturbing portion is protrudingly disposed at a position where the conductive bumps for mounting of a flip-chip semiconductor chip are loosely arranged, such that gap between the flip-chip semiconductor chip and the package substrate or gap between the fluid-disturbing portion and the conductive bumps can be reduced, thereby increasing capillary attraction of capillary phenomenon and further balancing flow rate of the underfill material between the conductive bumps that are arranged at different intervals. As a result, voids formation and subsequent popcorn effect or delamination problem can be prevented.

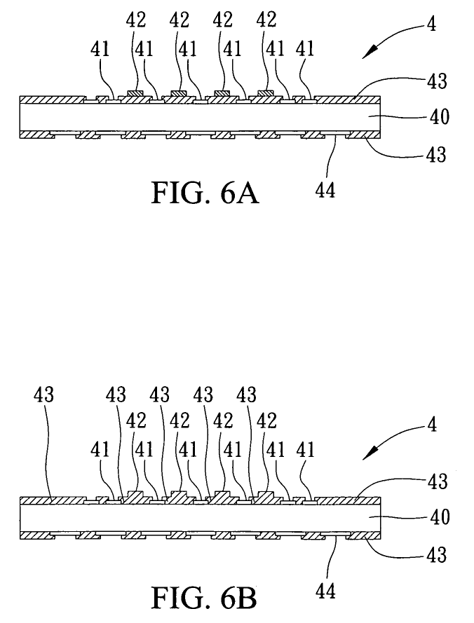

FIGS. 6A and 6B are sectional diagrams showing a package substrate applicable to a flip-chip semiconductor package structure according to a second embodiment of the present invention.

The package substrate of the present embodiment is similar to that of the first embodiment. A main difference of the package substrate of the present embodiment from the first embodiment is the body 40 of the package substrate 4 is completely covered by a solder mask layer 43. The solder mask layer 43 has a plurality of openings for exposing the solder pads 41 disposed in the chip-attach area. The solder mask layer 43 also has openings for exposing the solder ball pads 44.

A fluid-disturbing portion 42 is disposed in the chip-attach area at a position where the solder pads 41 are loosely arranged. The fluid-disturbing portion 42 can be an epoxy resin or a solder mask layer that is protrudingly disposed on the solder mask layer 43 located in the chip-attach area, as shown in FIG. 6A.

In addition, the fluid-disturbing portion 42 can be formed by directly increasing thickness of the solder mask layer 43 that is located at a position where the solder pads 41 are loosely arranged while the solder mask layer 43 is formed on the body 40 of the package substrate, as shown in FIG. 6B.

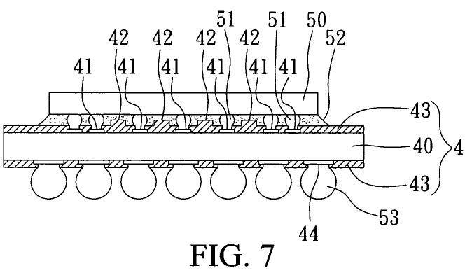

FIG. 7 is a sectional diagram of a flip-chip semiconductor package structure according to a second embodiment of the present invention, wherein the package substrate of FIG. 6B is used. A flip-chip semiconductor chip 50 is mounted on and electrically connected with the solder pads 41 in the chip-attach area through a plurality of conductive bumps 51. An underfill material 52 is filled between the flip-chip semiconductor chip 50 and the package substrate 4, wherein flow rate of the underfill material 52 between the conductive bumps 51 that are arranged at different intervals can be balanced by the fluid-disturbing portion 42. Further, solder balls 53 are mounted on the solder ball pads 44 such that the flip-chip semiconductor chip 50 can be electrically connected with an external device through the solder balls 53.

The above-described descriptions of the detailed embodiments are only to illustrate the preferred implementation according to the present invention, and it is not to limit the scope of the present invention, Accordingly, all modifications and variations completed by those with ordinary skill in the art should fall within the scope of present invention defined by the appended claims.

What is claimed is:

1. A package substrate, comprising:
a body having at least a chip-attach area disposed thereon;
a plurality of solder pads disposed in the chip-attach area and arranged at different intervals; and
a fluid-disturbing portion disposed in the chip-attach area at a position where the solder pads are loosely arranged.

2. The package substrate of claim 1, wherein a solder mask layer covers surfaces of the body and an opening is formed in the solder mask layer for exposing the chip-attach area.

3. The package substrate of claim 2, wherein, opposite to the surface of the package substrate with the solder pads disposed thereon, another surface of the package substrate is disposed with a plurality of solder ball pads, which is exposed from the solder mask layer.

4. The package substrate of claim 2, wherein the fluid-disturbing portion is one of an epoxy resin and a solder mask layer protrudingly disposed on the body.

5. The package substrate of claim 4, wherein the fluid-disturbing portion is formed by screen printing or is laid in the chip-attach area at the same time when the solder mask layer is formed on surfaces of the body.

6. The package substrate of claim 1, wherein a solder mask layer completely covers surfaces of the body and the solder mask layer has openings formed for exposing the solder pads in the chip-attach area.

7. The package substrate of claim 6, wherein, the fluid-disturbing portion is one of an epoxy resin and a solder mask layer protrudingly disposed on the solder mask layer.

8. The package substrate of claim 6, wherein the fluid-disturbing portion is formed by directly increasing thickness of the solder mask layer located at a position where the solder pads are loosely arranged.

9. A flip-chip semiconductor package structure, comprising:
a package substrate including a body having at least a chip-attach area disposed thereon, a plurality of solder pads disposed in the chip-attach area and arranged at different intervals, and a fluid-disturbing portion disposed in the chip-attach area at a position where the solder pads are loosely arranged;
a flip-chip semiconductor chip mounted on and electrically connected to the solder pads in the chip-attach area through a plurality of conductive bumps; and
an underfill material filled between the package substrate and the flip-chip semiconductor chip and encapsulating the conductive bumps and the fluid-disturbing portion.

10. The package structure of claim 9, wherein a solder mask layer covers surfaces of the body and an opening is formed in the solder mask layer for exposing the chip-attach area.

11. The package structure of claim 10, wherein, opposite to the surface of the package substrate with the solder pads disposed thereon, another surface of the package substrate is disposed with a plurality of solder ball pads, which is exposed from the solder mask layer.

12. The package structure of claim 11, wherein solder balls are mounted on the solder ball pads.

13. The package structure of claim 10, wherein the fluid-disturbing portion is one of an epoxy resin and a solder mask layer protrudingly disposed on the body.

14. The package structure of claim 13, wherein the fluid-disturbing portion is formed by screen printing or is laid in the chip-attach area at the same time when the solder mask layer is formed on surfaces of the body.

15. The package structure of claim 9, wherein a solder mask layer completely covers surfaces of the body and the solder mask layer has openings formed for exposing the solder pads in the chip-attach area.

16. The package structure of claim 15, wherein, the fluid-disturbing portion is one of an epoxy resin and a solder mask layer protrudingly disposed on the solder mask layer.

17. The package structure of claim 15, wherein the fluid-disturbing portion is formed by directly increasing thickness of the solder mask layer located at a position where the solder pads are loosely arranged.

18. The package structure of claim 9, wherein thickness and width of the fluid-disturbing portion are designed such that capillary rate induced by distance between the fluid-disturbing portion and the flip-chip semiconductor chip and the capillary rate induced by distance between the fluid-disturbing portion and the conductive bumps are close to or same as capillary rate at a position where the conductive bumps are closely arranged.
